(19) United States
(12) Patent Application Publication
(10) Pub. No.: US 2017/0077038 A1
(43) Pub. Date: Mar. 16, 2017

(54) SEMICONDUCTOR DEVICE

(71) Applicant: KABUSHIKI KAISHA TOSHIBA, Tokyo (JP)

(72) Inventors: Makoto MIZUKAMI, Ibo Hyogo (JP); Junichi UEHARA, Himeji Hyogo (JP)

(21) Appl. No.: 15/062,205

(22) Filed: Mar. 7, 2016

(30) Foreign Application Priority Data
Sep. 11, 2015 (JP) 2015-179131

(51) Int. Cl. H01L 23/544; H01L 29/36; H01L 29/16; H01L 29/06

(52) U.S. Cl. CPC H01L 23/544; H01L 29/0611; H01L 29/36; H01L 29/1608; H01L 29/0657; H01L 2223/54433

(57) ABSTRACT

A semiconductor device includes a first identification mark that is identifiable by a photoluminescence method, and a second identification mark that is identifiable using visible light.

### CROSS-REFERENCE TO RELATED APPLICATION

This application is based upon and claims the benefit of priority from Japanese Patent Application No. 2015-179131, filed on Sep. 11, 2015, the entire contents of which are incorporated herein by reference.

### FIELD

Embodiments described herein relate generally to a semiconductor device.

### BACKGROUND

Crystal defects in a semiconductor layer can reduce reliability and cause failure of a semiconductor device. For example, in a semiconductor device which uses a SiC substrate, stacking fault (SF), which grows from a basal plane dislocation (BPD) of the SiC substrate during operation of the device, is known to reduce the reliability and cause failure of the SiC device. It would be desirable to identify and separate semiconductor chips that can fail for the above reasons during die sort.

### DESCRIPTION OF THE DRAWINGS

FIG. 1 is a schematic top view of a semiconductor device according to a first embodiment.

FIG. 2 is a schematic sectional view of the semiconductor device according to the first embodiment.

FIGS. 3A and 3B are schematic views of a first identification mark according to the first embodiment.

FIGS. 4A and 4B are schematic views of a second identification mark according to the first embodiment.

FIGS. 5A and 5B are explanatory diagrams of a test method of the semiconductor device according to the first embodiment.

FIGS. 6A and 6B are schematic views of a first identification mark and a second identification mark according to a second embodiment.

FIGS. 7A and 7B are schematic views of a first identification mark and a second identification mark according to a third embodiment.

### DETAILED DESCRIPTION

Embodiments provide a semiconductor device with improved reliability.

In general, according to one embodiment, a semiconductor device includes a first identification mark that is identifiable by a photoluminescence method, and a second identification mark that is identifiable using visible light.

Hereinafter, exemplary embodiments will be descried with reference to the drawings. In the following description, the same symbols or reference numerals will be given to the same or similar elements, and description of the elements described once will only be repeated as needed.

In addition, in the following description, notation of n⁺, n and n⁻, and p⁺, p and p⁻ represents relative levels of impurity concentrations of each conductive type. That is, n⁺-type impurity concentration is higher than n-type impurity concentration, and n⁻-type impurity concentration is lower than n-type impurity concentration. In addition, p⁺-type impurity concentration is higher than p-type impurity concentration, and p⁻-type impurity concentration is lower than p-type impurity concentration. There is a case in which n⁺ and n⁻ are simply described as an n type, and p⁺ and p⁻ are simply described as a p type.

### FIRST EMBODIMENT

A semiconductor device according to the present embodiment includes a first identification mark which is identifiable by a photoluminescence method, and a second identification mark which is identifiable using visible light.

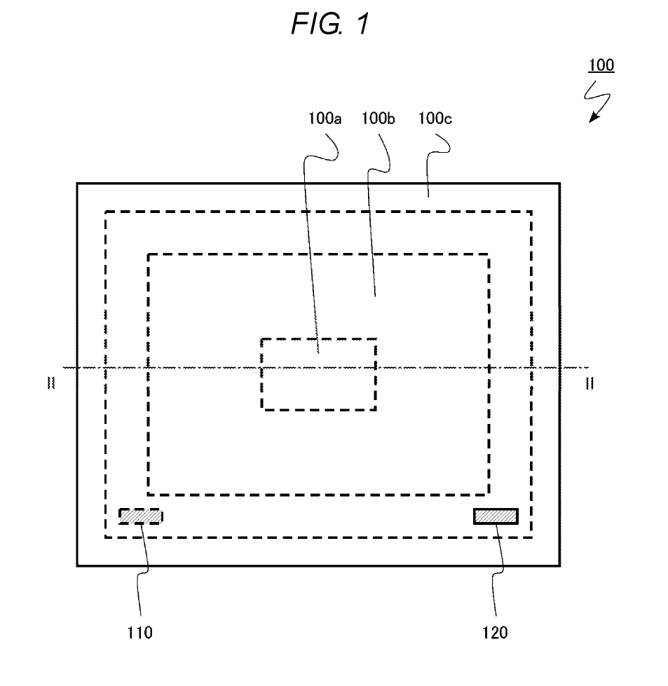

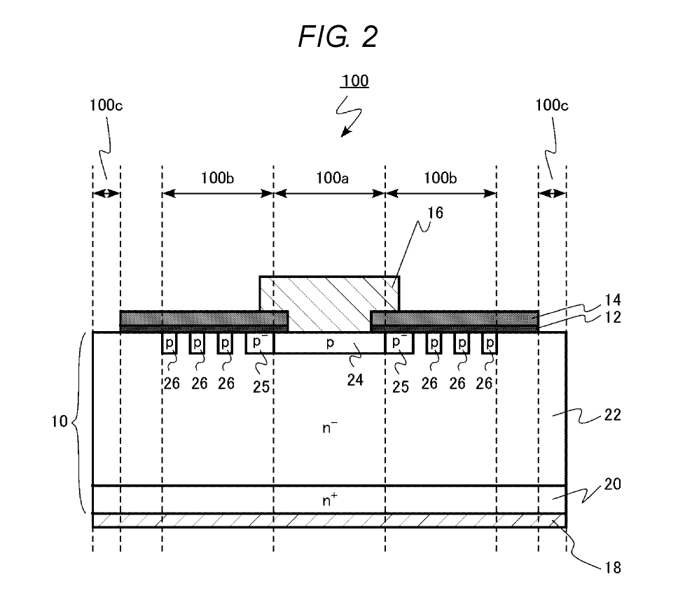

FIG. 1 is a schematic top view of a semiconductor device according to the present embodiment. FIG. 2 is a schematic sectional view of the semiconductor device according to the present embodiment. FIG. 2 is a cross-sectional view taken along line II-II in FIG. 1. The semiconductor device according to the present embodiment is a PIN diode which uses a SiC substrate.

The PIN diode 100 includes an element region 100a, a termination region 100b, a dicing region 100c, a first identification mark 110, and a second identification mark 120. The element region 100a is surrounded by the termination region 100b. The termination region 100b is surrounded by the dicing region 100c.

The element region 100a functions as a region through which a current flows at the time of a forward bias of the PIN diode 100.

The termination region 100b functions as an area in which strength of an electric field that is applied to an end portion of the element region 100a is reduced at the time of a reverse bias of the PIN diode 100, and a breakdown voltage of an element of the PIN diode 100 increases. The termination region 100b has, for example, a RESURF structure or a guard ring structure.

The dicing region 100c is a planned cutting region which is used for dividing a semiconductor layer into a plurality of semiconductor chips. In the present disclosure, a portion of the dicing region 100c remaining in the semiconductor chip after being cut is also simply referred to as the dicing region 100c.

The first identification mark 110 and the second identification mark 120 are provided in a region between the termination region 100b and the dicing region 100c. In other words, the first identification mark 110 and the second identification mark 120 are provided in a region which is provided such that a termination region 100b is between the element region 100a and the region.

The PIN diode 100 includes a semiconductor layer 10, a base oxide film (first insulating film) 12, an interlayer insulating film (second insulating film) 14, an anode electrode 16, and a cathode electrode 18. An n⁺-type cathode region 20, an n⁻-type drift region 22, a p-type anode region 24, a p⁻-type RESURF region 25, and a p-type guard ring region 26 are provided in the semiconductor layer 10.

The p-type anode region 24 is provided in the element region 100a. The p-type RESURF region 25 is provided in the termination region 100b. The p-type RESURF region 25 is provided in a ring shape so as to surround the p-type anode region 24. The p-type RESURF region 25 comes into contact with the p-type anode region 24. The p⁻-type RESURF region 25 contains p-type impurity concentration lower than that of the p-type anode region 24. The p-type guard ring region 26 is provided in the termination region 100b. A plurality of p-type guard ring regions 26 are provided, and each of the p-type guard ring regions 26 has a ring shape.

The semiconductor layer 10 is a semiconductor with a bandgap wider than that of silicon. The semiconductor layer 10 is, for example, a SiC layer with a 4H—SiC structure. A thickness of the semiconductor layer 10 is, for example, greater than 5 μm and smaller than 600 μm.

The base oxide film 12 is, for example, a thermal oxide film, for example, a silicon oxide film.

The interlayer film 14 is a deposited film which is formed by, for example, a chemical vapor deposition (CVD) method. The interlayer film 14 is, for example, a silicon oxide film.

The first identification mark 110 is a mark which is identifiable by a photoluminescence method (PL method). The photoluminescence method is a method of observing emitted light when a material is irradiated with light and electrons excited by the light transition to a ground state. For example, ultraviolet laser is used as the exciting light. It is possible to evaluate, for example, crystal defect of single crystal, or impurity, using a photoluminescence method.

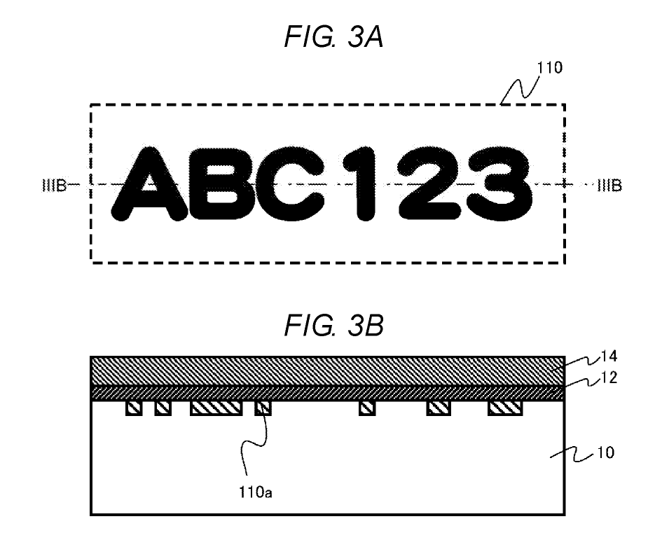

FIGS. 3A and 3B are schematic views of a first identification mark according to the present embodiment. FIG. 3A is a top view, and FIG. 3B is a cross-sectional view taken along line IIIB-IIIB of FIG. 3A.

The first identification mark 110 includes, for example, a character string as illustrated in FIG. 3A. A one-dimensional or two-dimensional bar code can also be applied to the first identification mark 110, in place of the character string.

The first identification mark 110 includes an amorphous SiC region (amorphous region) 110a. The amorphous SiC region 110a is provided in the semiconductor layer 10. The amorphous SiC region 110a is formed so as to become, for example, a pattern of a character string.

For example, the amorphous SiC region 110a can be formed by selectively injecting argon (Ar) into the semiconductor layer 10, by an ion injection method. In addition, for example, the amorphous SiC region 110a can be formed by selectively irradiating the semiconductor layer 10 with an electron beam.

As the amorphous SiC region 110a is provided in the semiconductor layer 10, the amorphous SiC region 110a emits light by a photoluminescence method, whereby the first identification mark 110 is identifiable.

A polycrystalline SiC region (polycrystalline) may be provided in place of the amorphous SiC region 110a. The amorphous SiC region 110a maybe, for example, a p-type impurity region formed by ion-injection of p type impurity such as aluminum (Al), or an n-type impurity region formed by ion-injection of n-type impurity such as nitride (N).

The second identification mark 120 is a mark which is identifiable using visible light. The visible light is, for example, light with a wavelength longer than or equal to 380 nm and shorter than or equal to 780 nm.

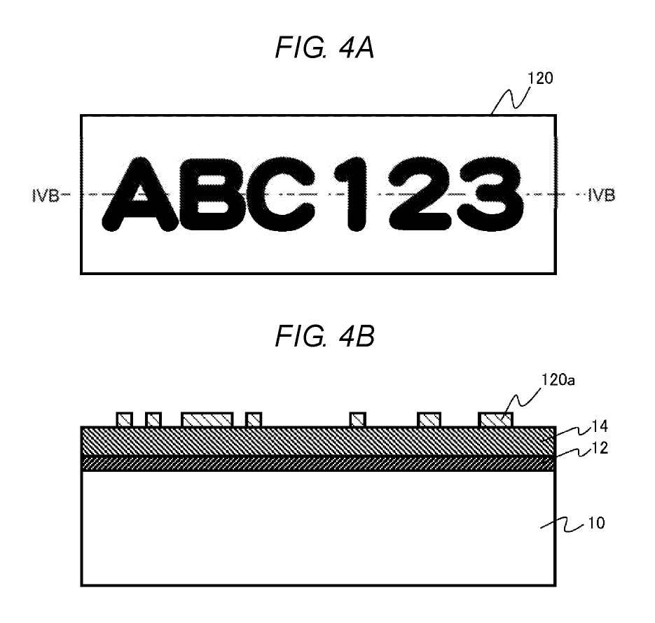

FIGS. 4A and 4B are schematic views of a second identification mark according to the present embodiment. FIG. 4A is a top view, and FIG. 4B is a cross-sectional view taken along line IVB-IVB of FIG. 4A.

The second identification mark 120 includes, for example, a character string as illustrated in FIG. 4A. A one-dimensional or two-dimensional bar code can also be applied to the second identification mark 120, in place of the character string.

The second identification mark 120 includes a metal region 120a. The metal region 120a is provided on the interlayer film 14. The metal region 120a is formed so as to become, for example, a pattern of a character string.

For example, the metal region 120a can be formed by patterning a metal film formed on the interlayer film 14. The metal region 120a can be formed at the same time as, for example, the anode electrode 16.

By providing the metal region 120a, it is possible to identify the second identification mark 120, using visible light.

In the present embodiment, the first identification mark 110 and the second identification mark 120 have the same pattern. However, other patterns can also be employed if association of the first identification mark 110 and the second identification mark 120 is made.

Next, a test method of the semiconductor device according to the present embodiment will be described with reference to FIG. 1 to FIG. 5B. In the test method of the semiconductor device according to the present embodiment, a plurality of first identification marks, which are different from each other and is identifiable by a photoluminescence method, are formed in a semiconductor layer; a plurality of second identification marks which are different from each other and is identifiable using visible light, are formed on the semiconductor layer; a crystal defect test is performed for the semiconductor layer, using the photoluminescence method; association of crystal defects detected by the crystal defect test and the first identification mark identified by the photoluminescence method, is made; and the second identification mark corresponding to the first identification mark is identified using visible light, whereby, a semiconductor chip having the first identification mark associated with the crystal defects is determined to be a failed product.

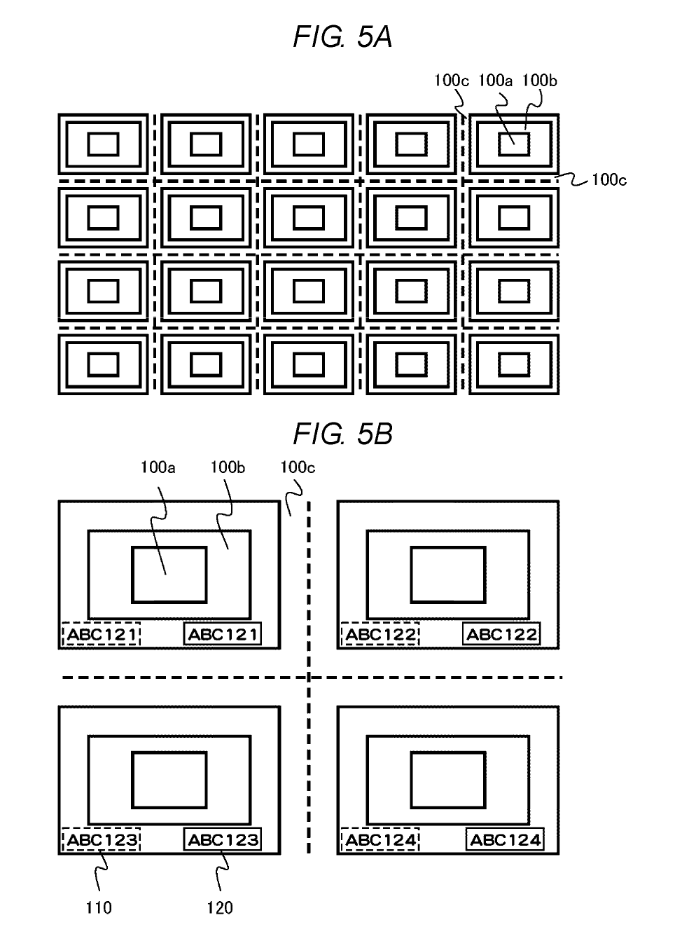

FIGS. 5A and 5B are explanatory diagrams of a test method of the semiconductor device according to the present embodiment. FIGS. 5A and 5B illustrate a state shortly before die sort of a semiconductor device which is tested by the test method of the semiconductor device according to the present embodiment. FIG. 5A is a top view of the semiconductor device, and FIG. 5B is an enlarged view of a partial region of FIG. 5A.

For example, a plurality of semiconductor chips are formed on the semiconductor layer 10. Each semiconductor chip is the PIN diode 100. The plurality of semiconductor chips are arranged in a matrix with the dicing region 100c interposed therebetween.

FIG. 5A illustrates a pattern corresponding to one shot when the pattern is formed on the semiconductor layer 10 by using a step-and-repeat method of lithography. That is, in the present embodiment, a pattern of 20 chips can be formed by one shot.

First, the semiconductor layer 10 including the n⁺-type cathode region 20 and the n⁻-type drift region 22 is prepared. The semiconductor layer 10 is a 4H—SiC substrate.

Subsequently, a pattern of the first identification mark 110 is formed on the semiconductor layer 10. Then, for example, the base oxide film 12 is formed by performing thermal oxidation of the semiconductor layer 10.

Subsequently, patterning of a photoresist film is performed to form a pattern corresponding to the first identification mark 110, by a lithography method. At this time, 20 chips which are formed by one shot include the first identification mark 110 which are different from each other.

Subsequently, ion injection of argon (Ar) is performed using the photoresist as a mask, and the amorphous SiC region 110a is formed.

Thereafter, a crystal defect test of the semiconductor layer 10 is performed by the photoluminescence method in a conventional manner. If crystal defect which can reduce reliability and cause failure is discovered, the first identification mark 110 of a chip corresponding to the crystal defect is identified by the same photoluminescence method. The first identification mark 110 of each of those chips in which the crystal defect is discovered is stored.

Thereafter, the p-type anode region 24, the p-type RESURF region 25, the p-type guard ring region 26, and the anode electrode 16 are formed by conventional process technology.

When the anode electrode 16 is formed, a pattern of the second identification mark 120 is formed at the same time. That is, the second identification mark 120 is formed by patterning the metal region 120a. The 20 chips which are formed by one shot includes unique second identification marks 120, each being associated with a different one the first identification marks 110.

Thereafter, the cathode electrode 18 is formed by the conventional process technology.

Subsequently, die sort, which sorts good products and failed products of the plurality of semiconductor devices that are manufactured, is performed. At the time of die sort, for example, the second identification marks 120 of each semiconductor chip are read using visible light. A semiconductor chip, which includes the second identification mark 120 corresponding to the first identification mark 110 of a chip in which crystal defect is discovered, is determined to be a failed product, and the second identification marks 110 of the failed products are recorded.

After the die sort, the semiconductor layer 10 is cut along the dicing region 100c using, for example, a dicing blade, whereby a plurality of semiconductor chips are diced.

Sorting and separating the failed products by reading the second identification marks 120 of each semiconductor chip using visible light are performed after the plurality of semiconductor chips are diced.

Next, effects of the present embodiment will be described.

Crystal defect of a semiconductor layer can cause failure of a semiconductor device. For example, in a SiC substrate, a BPD included in the SiC substrate is propagated into the SiC layer, when epitaxial growth of the SiC layer is performed on the SiC substrate. BPD which reaches the surface of the SiC layer among the BPD propagated into the SiC layer is expanded during operation of the semiconductor device. Such an expansion of stacking fault (SF) causes failure in the form of variation of an ON voltage or the like. However, it is difficult to identify the reduction in the reliability by electrical evaluation shortly after the semiconductor device is manufactured.

A line defect such as BPD, which is one of crystal defects which can cause failure, cannot be discovered during the test which uses visible light. However, the defect can be discovered when crystal defect test is carried out using a photoluminescence method, for example, before manufacture of the semiconductor chip, or during the manufacture. However, since a plurality of semiconductor chips are formed in the semiconductor layer, it is difficult to associate the discovered crystal defect with the semiconductor chips.

For example, it is considered that association is performed using positional information of a stage on which a semiconductor layer is mounted. However, in this method, particularly, sufficient accuracy cannot be obtained if a size of the semiconductor chip decreases, and the association becomes difficult to be made.

In the present embodiment, the first identification mark 110 which is identifiable by the photoluminescence method is provided in semiconductor chip. The first identification marks 110 are unique among the plurality of semiconductor chips formed in the semiconductor layer.

Hence, it is possible to associate crystal defects, which are discovered when the crystal defect test is carried out using the photoluminescence method before the manufacture of the semiconductor chip or during the manufacture, with a particular semiconductor chip using the first identification mark 110.

Furthermore, it is possible to easily identify the failed semiconductor chips after the semiconductor chip is manufactured, using the second identification mark 120 which is identifiable using visible light based on the association between the first identification mark 110 and the second identification mark 120 that is made when the second identification mark 120 is formed.

In the semiconductor device according to the present embodiment, it is possible to sort a semiconductor chip which can result in failure due to crystal defects, as a failed product. Hence, it is possible to provide a semiconductor device with improved reliability.

### SECOND EMBODIMENT

A semiconductor device according to the present embodiment is the same as the semiconductor device according to the first embodiment except that the second identification mark includes a partial region of the second insulating film provided in gaps between the first insulating films on the semiconductor layer with a bandgap wider than that of silicon, and the first identification mark includes an amorphous region, polycrystalline region, and an n-type impurity region or a p-type impurity region. Hence, the description which overlaps with that of the first embodiment will be omitted.

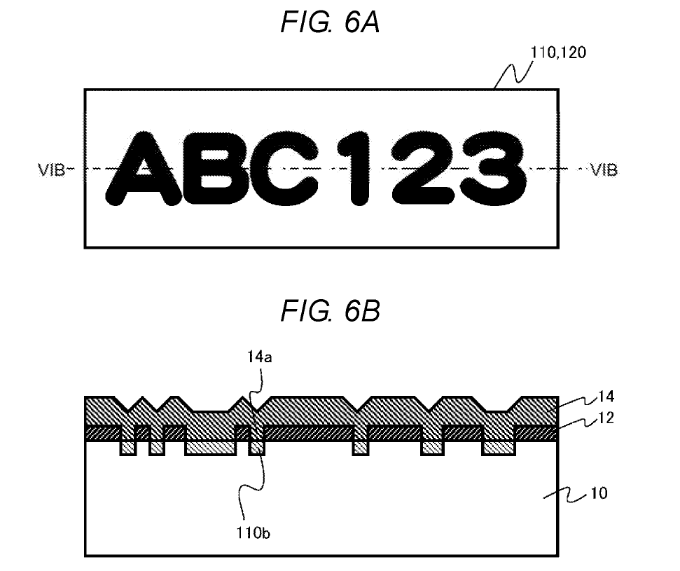

FIGS. 6A and 6B are schematic views of the first identification mark and the second identification mark according to the second embodiment. FIG. 6A is a top view, and FIG. 6B is a cross-sectional view taken along line VIB-VIB of FIG. 6A.

In the present embodiment, the first identification mark 110 and the second identification mark 120 are provided in the same position in a planar view.

The first identification mark 110 and the second identification mark 120 include, for example, character strings, as illustrated in FIG. 6A. In place of the character string, a one-dimensional or two-dimensional bar code can be used.

The first identification mark 110 includes a p-type SiC region (p-type impurity region) 110b which contains p-type impurity. The p-type impurity is, for example, aluminum (Al).

The p-type SiC region 110b is provided in the semiconductor layer 10. The p-type SiC region 110b is formed so as to be a pattern of, for example, a character string.

By providing the p-type SiC region 110b in the semiconductor layer 10 of single crystal, the p-type SiC region 110b emits light by the photoluminescence method, and the first identification mark 110 is identifiable.

The second identification mark 120 includes a partial region 14a of the interlayer insulating film (second insulating film) 14 which is interposed in gaps between the base oxide films (first insulating film) 12 that is provided on the semiconductor layer 10. The partial region 14a is formed so as to be a pattern of, for example, a character string.

Roughness is formed on an upper surface of the region 14a of the interlayer insulating film 14. Since the roughness is formed on the upper surface of the region 14a, it is possible to identify the second identification mark 120, using visible light.

The p-type SiC region 110b is provided in the semiconductor layer 10 under the region 14a.

The first identification mark 110 and the second identification mark 120 can be formed by the following method.

First, the base oxide film 12 is formed on the semiconductor layer 10. Subsequently, patterning of a photoresist film is performed in a pattern corresponding to the first identification mark 110 by a lithography method.

Ion injection of p-type impurity into the semiconductor layer 10 is performed using the patterned base oxide film 12 as a mask, and the p-type SiC region 110b is formed in the semiconductor layer 10 under gaps in the base oxide film 12.

Subsequently, the interlayer insulating film 14 is stacked on the base oxide film 12. The gaps in the base oxide film 12 is filled with the interlayer insulating film 14. The groove portion of the base oxide film 12 filled with the interlayer insulating film 14 becomes the region 14a. Roughness is formed on an upper surface of the region 14a of the interlayer insulating film 14.

In place of the p-type SiC region 110b, an n-type SiC region (n-type impurity region) containing n-type impurity can also be applied. In addition, in place of the p-type SiC region 110b, an amorphous SiC region (amorphous region) or a polycrystalline SiC region (polycrystalline region) can also be applied.

In the semiconductor device according to the present embodiment, in the same manner as in the first embodiment, it is possible to sort a semiconductor chip which can result in reliability failure due to crystal defects, as a failed product. Hence, it is possible to provide a semiconductor device with improved reliability.

In addition, the first identification mark 110 and the second identification mark 120 are provided in the same position in a planar view. For this reason, it is possible to reduce an area necessary for providing the first identification mark 110 and the second identification mark 120. In addition, the first identification mark 110 and the second identification mark 120 are easily formed.

### THIRD EMBODIMENT

A semiconductor device according to the present embodiment is the same as the semiconductor device according to the first embodiment except for the second identification mark includes a concave portion provided on a surface of a semiconductor layer, and the first identification mark includes an amorphous region, a polycrystalline region, an n-type impurity region or a p-type region which is provided in a semiconductor layer under the concave portion. Hence, the description which overlaps with that of the first embodiment will be omitted.

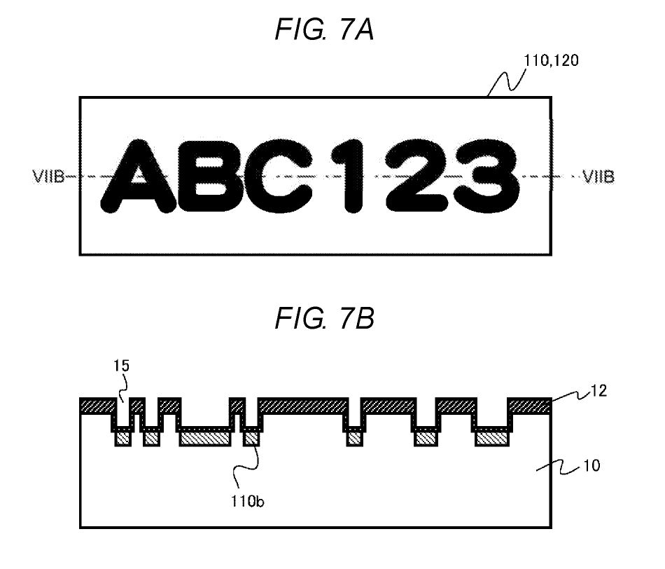

FIGS. 7A and 7B are schematic views of the first identification mark and the second identification mark according to the present embodiment. FIG. 7A is a top view, and FIG. 7B is a cross-sectional view taken along line VIIB-VIIB of FIG. 7A.

In the present embodiment, the first identification mark 110 and the second identification mark 120 are provided in the same position in a planar view.

The first identification mark 110 and the second identification mark 120 include, for example, character strings, as illustrated in FIG. 7A. In place of the character string, a one-dimensional or two-dimensional bar code can be used.

The first identification mark 110 includes a p-type SiC region (p-type impurity region) 110b which contains p-type impurity. The p-type impurity is, for example, aluminum (Al).

The p-type SiC region 110b is provided in the semiconductor layer 10. The p-type SiC region 110b is formed so as to be a pattern of, for example, a character string.

By providing the p-type SiC region 110b in the semiconductor layer 10 of single crystal, the p-type SiC region 110b emits light by the photoluminescence method, and the first identification mark 110 is identifiable.

The second identification mark 120 includes a concave portion (groove) 15 which is provided on a surface of the semiconductor layer 10. The concave portion 15 is formed so as to be a pattern of, for example, a character string.

Roughness is formed on the surface of the semiconductor layer 10 and an upper surface of the base oxide film 12. Since the roughness is formed on the surface of the semiconductor layer 10 and the upper surface of the base oxide film 12, it is possible to identify the second identification mark 120, using visible light.

The p-type SiC region 110b is provided in the semiconductor layer 10 under the concave portion 15.

In the present embodiment, for example, an interlayer insulating film is not provided on the base oxide film 12.

The first identification mark 110 and the second identification mark 120 can be formed by the following method.

First, a mask member is formed on the semiconductor layer 10. The mask member is, for example, a silicon oxide film. Subsequently, patterning of a photoresist film is performed on the mask member in a pattern corresponding to the first identification mark 110 by a lithography method.

Subsequently, patterning of the mask member is performed by reactive ion etching (RIE). Subsequently, the photoresist film is removed.

Subsequently, the semiconductor layer 10 is etched by the RIE, using the mask member as a mask, and the concave portion 15 is formed. Subsequently, ion injection of p type impurity into the semiconductor layer 10 is performed using the mask member as a mask, and the p-type SiC region 110b is formed in the semiconductor layer 10 under the concave portion 15.

Subsequently, the mask member is removed, and the base oxide film 12 is formed by thermal oxidation. Roughness is formed on the surface of the semiconductor layer 10 and the upper surface of the base oxide film 12.

In place of the p-type SiC region 110b, an n-type SiC region (n-type impurity region) containing n-type impurity can be applied. In addition, in place of the p-type SiC region 110b, an amorphous SiC region (amorphous region) or a polycrystalline SiC region (polycrystalline region) can be applied.

In addition, in the present embodiment, a case in which the concave portion 15 is formed on the surface of the semiconductor layer 10 and the concave portion 15 is used for the second identification mark 120 is used as an example. However, for example, it is possible that the concave portion 15 is not provided on the surface of the semiconductor layer 10, the mask member which is used as a mask of ion injection is left without being removed, and the roughness of the mask member is used for the second identification mark 120.

In the semiconductor device according to the present embodiment, in the same manner as in the first embodiment, it is possible to sort a semiconductor chip which can result in failure due to crystal defects, as a failed product. Hence, it is possible to provide a semiconductor device with improved reliability.

In addition, the first identification mark 110 and the second identification mark 120 are provided in the same position in a planar view. For this reason, it is possible to reduce an area necessary for providing the first identification mark 110 and the second identification mark 120. In addition, the first identification mark 110 and the second identification mark 120 are easily formed.

In the first to third embodiments, a case in which the first identification mark 110 and the second identification mark 120 are provided between the termination region 100b and the dicing region 100c is used as an example. However, the first identification mark 110 and the second identification mark 120 can also be provided in the dicing region 100c. This form is effective in a case space for providing the first identification mark 110 and the second identification mark 120 is not able to be ensured in a semiconductor chip.

In the first to third embodiments, the PIN diode is used as an example, but embodiments can be applied to other devices, such as, a Schottky barrier diode, a metal oxide semiconductor field effect transistor (MOSFET), a metal insulator semiconductor field effect transistor (MISFET), or an insulated gate bipolar transistor (IGBT).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device comprising:
a first identification mark that is identifiable by a photoluminescence method; and
a second identification mark that is identifiable using visible light.

2. The device according to claim 1, wherein the first identification mark includes an amorphous region or a polycrystalline region that is provided in a semiconductor layer with a bandgap wider than a bandgap of silicon.

3. The device according to claim 1, wherein the first identification mark includes an n-type impurity region or a p-type impurity region that is provided in a semiconductor layer with a bandgap wider than a bandgap of silicon.

4. The device according to claim 1, wherein the first identification mark and the second identification mark are provided in a region that surrounds a termination region that surrounds an element region.

5. The device according to claim 4, further comprising:
a semiconductor layer in which the element region and the termination region are formed, wherein
locations of the first identification mark and the second identification mark in the region are aligned in a direction normal to a surface of the semiconductor layer.

6. The device according to claim 5, further comprising:
a first insulating layer on the surface of the semiconductor layer, having gaps; and
a second insulating layer on the first insulating layer, wherein
the roughness along a surface of the second insulating layer caused by the gaps in the first insulating layer defines the second identification mark.

7. The device according to claim 5, further comprising:
an insulating layer on the surface of the semiconductor layer, having gaps that define the second identification mark.

8. The device according to claim 7, wherein the semiconductor layer is a SiC layer.

9. The device according to claim 9, wherein the photoluminescence method includes irradiation of the first identification mark with light having shorter wavelengths than visible light.

10. The device according to claim 9, wherein the photoluminescence method includes irradiation of the first identification mark with ultraviolet light.

11. A semiconductor device comprising:
a first identification mark formed of a semiconductor having high and low impurity concentrations, wherein portions having the high impurity concentration become distinguishable from portions having the low impurity concentration when the first identification mark is irradiated with light that is in a first wavelength range; and
a second identification mark that is identifiable when the second identification mark is irradiated with light that is in a second wavelength range that does not overlap with the first wavelength length.

12. The device according to claim 11, wherein the second wavelength range spans wavelengths of visible light.

13. The device according to claim 11, wherein wavelengths in the first wavelength range are shorter than wavelengths in the second wavelength range.

14. The device according to claim 11, wherein wavelengths in the first wavelength range are ultraviolet wavelengths.

15. The device according to claim 11, wherein the light that is in the first wavelength range is employed during detection of crystal defects.

16. The device according to claim 11, wherein the first identification mark and the second identification mark are provided in a region that surrounds a termination region that surrounds an element region.

17. The device according to claim 16, further comprising:
a semiconductor layer in which the element region and the termination region are formed, wherein
locations of the first identification mark and the second identification mark in the region are aligned in a direction normal to a surface of the semiconductor substrate.

18. The device according to claim 17, further comprising:
a first insulating layer on the surface of the semiconductor layer, having gaps; and
a second insulating layer on the first insulating layer, wherein
the roughness along a surface of the second insulating layer caused by the gaps in the first insulating layer defines the second identification mark.

19. The device according to claim 17, further comprising:
an insulating layer on the surface of the semiconductor layer, having gaps that define the second identification mark.

20. The device according to claim 19, wherein the semiconductor layer is a SiC layer.
